(19) United States
(12) Patent Application Publication
(10) Pub. No.: US 2010/0084117 A1
(43) Pub. Date: Apr. 8, 2010

(54) PLATEN COOLING MECHANISM FOR CRYOGENIC ION IMPLANTING

(76) Inventors: Roger B. Fish, Bedford, MA (US); Samuel M. Barsky, Wakefield, MA (US); Steven Michael Anella, West Newbury, MA (US)

Correspondence Address: Nields, Lemack & Frame, LLC, 176 E. MAIN STREET, SUITE 5, WESTBOROUGH, MA, 01581, US

(21) Appl. No.: 12/244,013

(22) Filed: Oct. 2, 2008

(51) Int. Cl. H05K 7/20; F25D 3/10; F28D 15/00

(52) U.S. Cl. 165/80.4; 361/702

(57) ABSTRACT

A system and method for altering and maintaining the temperature of a workpiece, especially at cryogenic temperatures, is disclosed. The platen on which the workpiece is located contains at least one inner conduit through which fluid can flow. An apparatus, in communication with a fluid source, is brought into contact with the platen. For example, an inlet and outlet on the platen and the ports of the apparatus may mate. Once the platen and the apparatus are successfully mated, fluid is passed through the apparatus and into the platen. Once the platen (and therefore the attached workpiece) has reached the desired temperature, the apparatus stops the flow of fluid through the platen. The apparatus and the platen then disengage. The platen is then free to move and rotated as required by the ion implantation process. When the platen temperature deviates from the desired temperature, the above process is repeated.

### BACKGROUND OF THE INVENTION

Ion implanters are commonly used in the production of semiconductor wafers. An ion source is used to create an ion beam, which is then directed toward the wafer. As the ions strike the wafer, they dope a particular region of the wafer. The configuration of doped regions defines their functionality, and through the use of conductive interconnects, these wafers can be transformed into complex circuits.

A block diagram of a representative ion implanter 100 is shown in FIG. 1. An ion source 110 generates ions of a desired species. In some embodiments, these species are atomic ions, which may be best suited for high implant energies. In other embodiments, these species are molecular ions, which may be better suited for low implant energies. These ions are formed into a beam, which then passes through a source filter 120. The source filter is preferably located near the ion source. The ions within the beam are accelerated/decelerated in column 130 to the desired energy level. A mass analyzer magnet 140, having an aperture 145, is used to remove unwanted components from the ion beam, resulting in an ion beam 150 having the desired energy and mass characteristics passing through resolving aperture 145.

In certain embodiments, the ion beam 150 is a spot beam. In this scenario, the ion beam passes through a scanner 160, which can be either an electrostatic or magnetic scanner, which deflects the ion beam 150 to produce a scanned beam 155-157. In certain embodiments, the scanner 160 comprises separated scan plates in communication with a scan generator. The scan generator creates a scan voltage waveform, such as a sine, sawtooth or triangle waveform having amplitude and frequency components, which is applied to the scan plates. In a preferred embodiment, the scanning waveform is typically very close to being a triangle wave (constant slope), so as to leave the scanned beam at every position for nearly the same amount of time. Deviations from the triangle are used to make the beam uniform. The resultant electric field causes the ion beam to diverge as shown in FIG. 1.

In an alternate embodiment, the ion beam 150 is a ribbon beam. In such an embodiment, there is no need for a scanner, so the ribbon beam is already properly shaped.

An angle corrector 170 is adapted to deflect the divergent ion beamlets 155-157 into a set of beamlets having substantially parallel trajectories. Preferably, the angle corrector 170 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil. Alternatively, other structures, such as parallelizing lenses, can also be utilized to perform this function.

Following the angle corrector 170, the scanned beam is targeted toward the workpiece 175. The workpiece is attached to a workpiece support. The workpiece support provides a variety of degrees of movement.

The workpiece support is used to both hold the wafer in position, and to orient the wafer so as to be properly implanted by the ion beam. To effectively hold the wafer in place, most workpiece supports typically use a circular surface on which the workpiece rests, known as a platen. Often, the platen uses electrostatic force to hold the workpiece in position. By creating a strong electrostatic force on the platen, also known as the electrostatic chuck, the workpiece or wafer can be held in place without any mechanical fastening devices. This minimizes contamination and also improves cycle time, since the wafer does not need to be unfastened after it has been implanted. These chucks typically use one of two types of force to hold the wafer in place: coulombic or Johnson-Rahbeck force.

The workpiece support typically is capable of moving the workpiece in one or more directions. For example, in ion implantation, the ion beam is typically a scanned or ribbon beam, having a width much greater than its height. Assume that the width of the beam is defined as the x axis, the height of the beam is defined as the y axis, and the path of travel of the beam is defined as the z axis. The width of the beam is typically wider than the workpiece, such that the workpiece does not have to be moved in the x direction. However, it is common to move the workpiece along the y axis to expose the entire workpiece to the beam.

In some applications, it is necessary to perform the desired ion implantation at certain temperatures. As an example, for cryogenic ion implantation, it is necessary to maintain the temperature of workpiece at very low temperatures, despite the fact that constant ion bombardment tends to increase its temperature. One method of achieving this is to pass low temperature fluids through conduits in the platen. These fluids can be gasses, such as helium, nitrogen, or carbon dioxide, or liquids, such as Fluorinert or liquid nitrogen. By keeping the platen extremely cold, the workpiece, by virtue of its physical contact with the platen, preserves its low operating temperature.

However, as described above, it is also typical for the workpiece support to move along the y axis to irradiate the entire surface of the workpiece. The workpiece, in certain situations, can also be rotated. These movements of the platen typically suggest the use of flexible tubing or some other pliable conduit to supply the fluid to the conduit in the platen. However, at cryogenic temperatures, the flexible tubing is susceptible to fatigue due to the bending stresses from the cyclic movement, and therefore cannot be used.

Thus, a system and method for maintaining the temperature of a workpiece, while not restricting its freedom of motion, is very desirable. Furthermore, the system and method is preferably immune to fatigue caused by constant bending.

### SUMMARY OF THE INVENTION

The problems of the prior art are overcome by the temperature control system described in the present disclosure. The disclosure provides a system and method for altering and maintaining the temperature of a workpiece, especially at cryogenic temperatures. The platen on which the workpiece is located contains at least one inner conduit through which fluid can flow.

In one embodiment, this inner conduit has an inlet and outlet on the side of the platen. The platen is brought into contact with an apparatus that has two corresponding ports. The inlet and outlet of the platen and the ports on the apparatus then mate together. Once the connection is made, the apparatus then begins the flow of fluid, such as nitrogen, through the conduit in the platen. Once the platen (and therefore the attached workpiece) has reached the desired temperature, the apparatus stops the flow of fluid through the platen. The apparatus and the platen then disengage. The platen is then free to move and rotate as required by the ion implantation process. When the platen temperature deviates from the desired temperature, the above process is repeated.

In a second embodiment, the inlet and outlet are on the underside of the platen. The apparatus connects the inlet and outlet of the platen via ports located on the top side of the apparatus. In some particular embodiments, the apparatus includes a movable portion that is brought into contact with the underside of the platen.

### BRIEF DESCRIPTION OF FIGURES

FIG. 1 represents a traditional ion implanter;

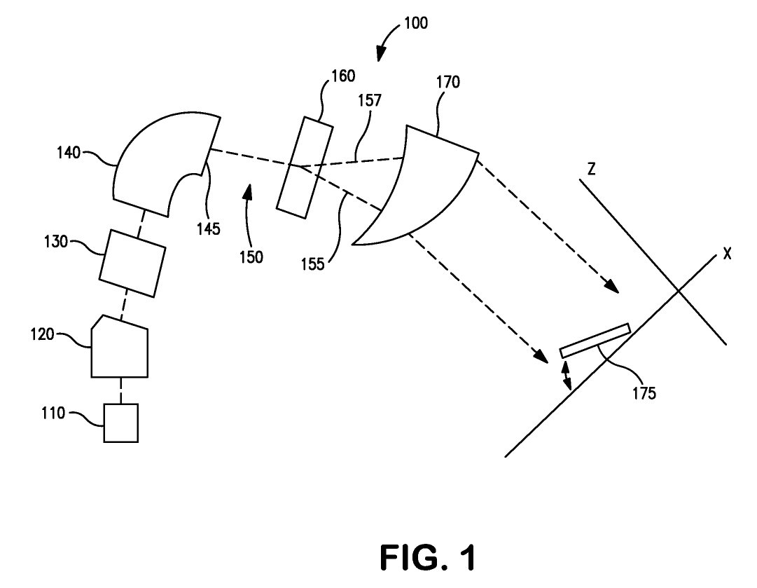

FIG. 2 represents a perspective view of a first embodiment of the apparatus to modify the temperature of the platen;

FIG. 3 represents a view of the apparatus of FIG. 2 in the operative, or docked, position;

FIG. 4 represents a view of the apparatus of FIG. 2 in the inoperative, or undocked, position;

FIG. 5a represents an isolated view of the apparatus;

FIG. 5b represents an expanded view of the mating portion of the apparatus shown in FIGS. 2-4;

FIG. 6 represents a perspective view of a second embodiment of the apparatus;

FIG. 7 represents a cross-section of the apparatus shown in FIG. 5 in the operative, or docked, position;

FIG. 8 represents a top view of the apparatus shown in FIG. 6 in the inoperative, or undocked, position; and

FIG. 9 represents a bottom view of the apparatus of FIG. 6 in the operative, or docked position.

### DETAILED DESCRIPTION OF THE INVENTION

Temperature plays an important role in ion implantation. While many ion implants are done at room temperature, there are benefits to performing implantation at high temperature or low temperature. For example, cryogenic ion implantation is beneficial in a number of applications, for example, in creating ultrashallow junctions in a crystalline silicon wafer.

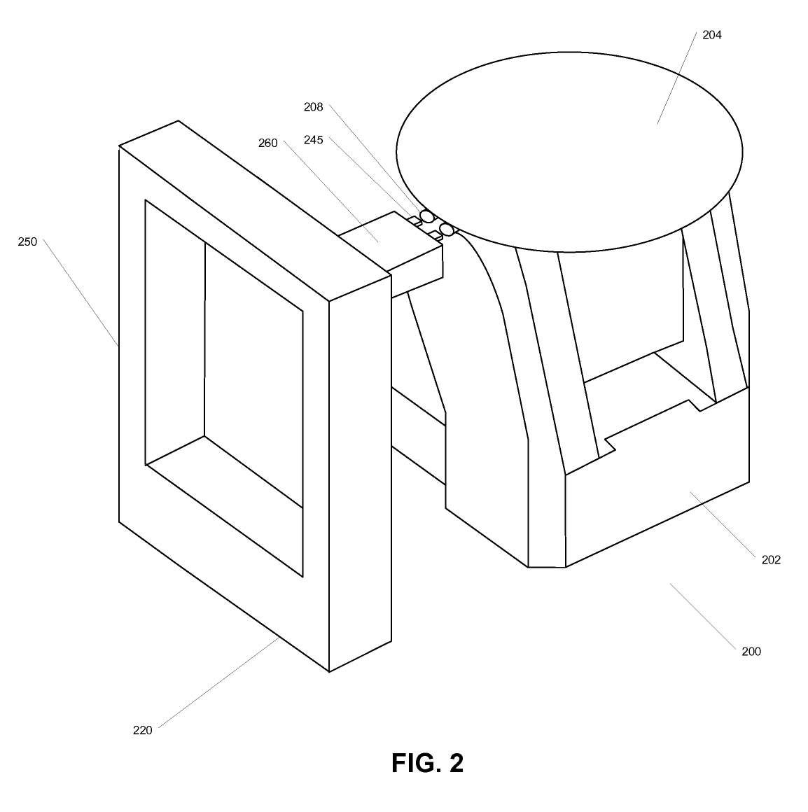

FIG. 2 illustrates a system for changing and regulating the temperature of workpiece in an ion implanter. The system affects the temperature of the workpiece by regulating the temperature of the supporting platen. FIG. 2 shows a perspective view of the apparatus 220 and also includes a roplat 200, comprising a base 202, a platen 204, and a motor (not shown). The base 202 of the roplat 200 is designed such that it can move the platen 204 in various directions, including axially and rotationally.

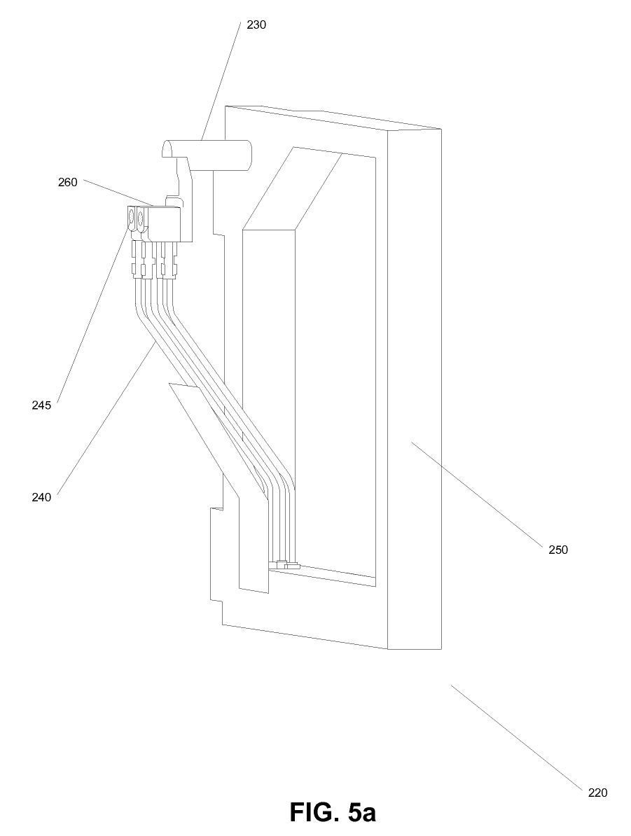

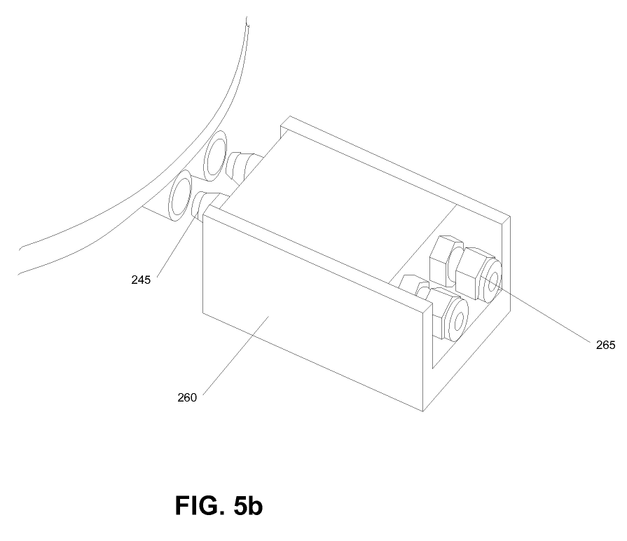

As best seen in FIG. 5a, the apparatus 220 preferably has an alignment mechanism 230, to insure that the platen 204 and apparatus 220 are properly positioned relative to one another. The apparatus 220 also includes a connection block 260. The connection block 260 attaches to two or more fluid conduits 240. The connection block 260 also includes the connectors 245, which mate with the ports 208 in the platen. The apparatus 220 may also include a mounting frame 250, which holds the alignment mechanism 230, the fluid conduits 240 and the connectors 245. Additionally, the apparatus 220 may include means to move toward the platen when connecting thereto. Such means may include an electric motor or other suitable mechanism.

One or more conduits are formed within the platen 204, which are used to circulate fluid, either gas or liquid, through the interior of the platen. The use of conduits to modify and/or regulate the temperature of the platen is highly effective, since the fluid passes through the interior of the platen, and therefore directly contacts the platen.

In one embodiment, shown in FIGS. 2-4, the conduit or conduits within platen 204 terminate in two or more ports 208 on the side of the platen 204. In certain embodiments, these termination ports 208 are simply openings in the side of the platen 204, similar to a female connector port. In other embodiments, these termination points 208 extend from the side of the platen 204 and include a connection mechanism, such as a male connector or tapered extending nozzle.

As described above, the ports 208 on the platen 204 are adapted to mate with the connectors 245 of the apparatus 220. The connectors 245 of the apparatus 220 may be tapered extending nozzles, or other suitable attachment mechanisms that can be press fit together with the ports 208 of the platen. Alternatively, the male portion of the connector can be on the platen, with the female portion on the apparatus. In some embodiments, the simpler piece of the mating mechanism is on the platen 204 to simplify packaging. In this scenario, the active component will be on the apparatus 220.

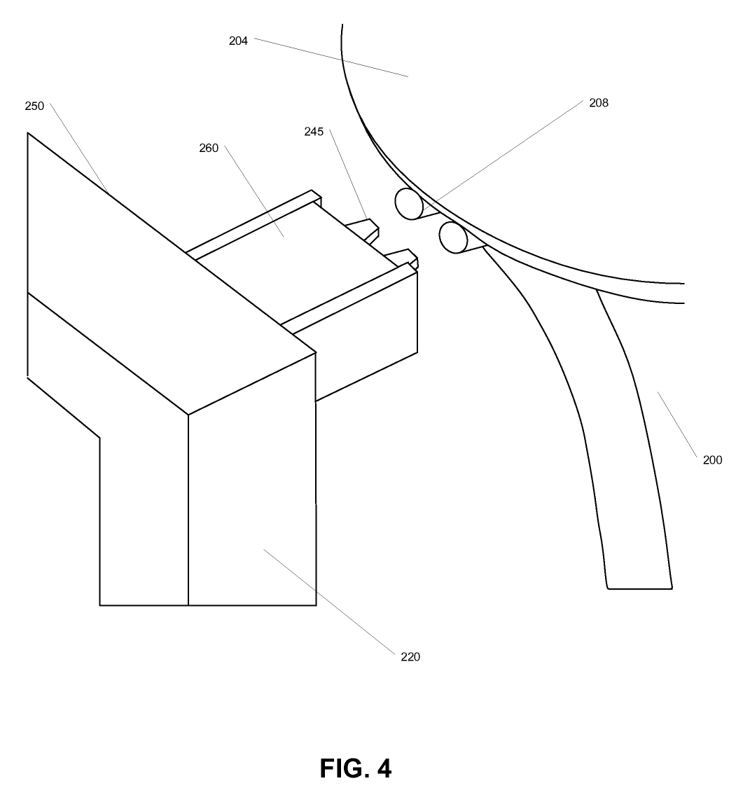

FIG. 4 shows a top view of the temperature regulating apparatus 220 retracted from the roplat 200 and platen 204. In this undocked position, the platen 204 is ready for ion implantation, as the temperature regulating apparatus 220 is not in the ion beam path and does not affect the ability of the roplat 200 to move and rotate the platen 204.

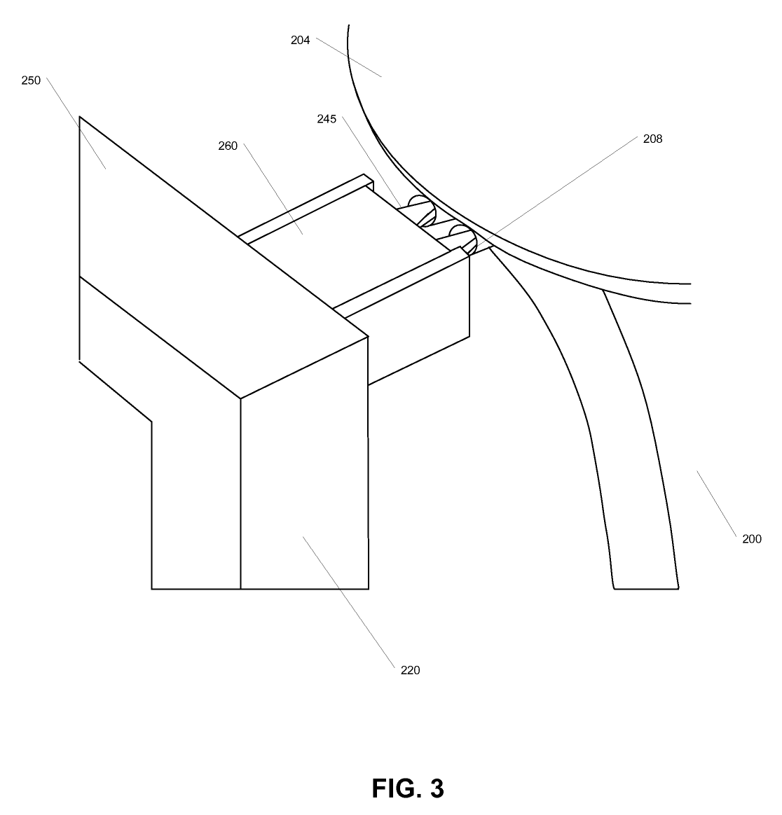

To regulate the temperature of the platen 204, the connectors 245 of the apparatus 220 must be brought into fluid communication with the conduit in the platen 204. FIG. 3 shows the apparatus 220 and roplat 200 in this operative docked position. The connector 245 of the apparatus preferably comprises tapered nozzles, so as to extend into the ports 208 on the platen 204. The tapered nozzles and ports form a fluid-tight seal. This eliminates the need for any manual intervention during the coupling and decoupling process. While not shown in the Figures, in some embodiments, coupling pressure alone may be insufficient. The apparatus may include local clamping force generated by a CAM or solenoid. Alternatively, the pressure of the coolant itself may be used to force a seal.

To initiate the process, the platen, if rotated, moves into its docked position, as shown in FIG. 3. In one embodiment, the temperature regulating apparatus 220 is able to move in an axial direction toward the roplat and specifically toward the platen 204, by virtue of a motor or other suitable mechanism, such that the connection nozzles 245 on the apparatus 220 properly mate with the corresponding ports 208 on the platen. This embodiment requires the use of flexible conduits between the wall enclosing the vacuum environment and the movable apparatus 220. As stated above, a fluid tight seal is achieved, preferably through a press fit technique, or a self-clamping mechanism. Alternatively, a locking mechanism to force a vacuum tight seal is activated via pressure, electrical current, a screw or other mechanisms to make the seal. As noted above, if such a locking mechanism is utilized, it is preferably mounted on the apparatus 220.

Once an integral seal has been made, fluid, in the form of gas or liquid, is circulated through the fluid conduits, the nozzles 245 and into the platen 204. After the platen reaches the desired temperature, the flow of fluid stops. In some embodiments, control valves are used to regulate the flow of fluid through the apparatus 220. The apparatus is then disengaged from the platen 204. In some embodiments, the residual fluid within the conduits and platen is removed via a low pressure return to insure that excess fluid does not contaminate the environment. In other embodiments, a gas, such as nitrogen, is passed through the conduits to purge any residual fluid.

In an alternate embodiment, the temperature regulating apparatus 220 is held in place and the roplat 200 is moved toward the apparatus 220 to engage with the alignment mechanism and the apparatus connectors 245.

FIG. 5b represents an expanded view of the connection block 260 of the apparatus 220. On one end of the block 260 is one or more couplers 265 to connect to fluid conduits which deliver the fluid to and from the platen. These couplers 265 may be traditional couplers used to connect conduits. Industry standard fittings, such as SwageLok®, can be used. Alternatively, a threaded pipe style fitting could be used. On the opposite end of the block are the connectors 245, used to connect to the platen 204. As shown in FIGS. 2 and 5a, the connection block 260 is mounted on mounting frame 250.

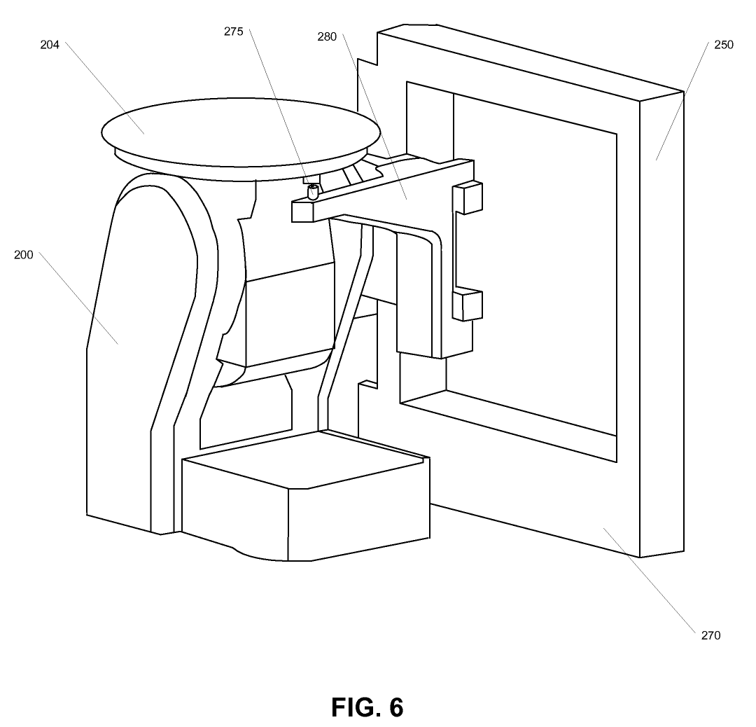

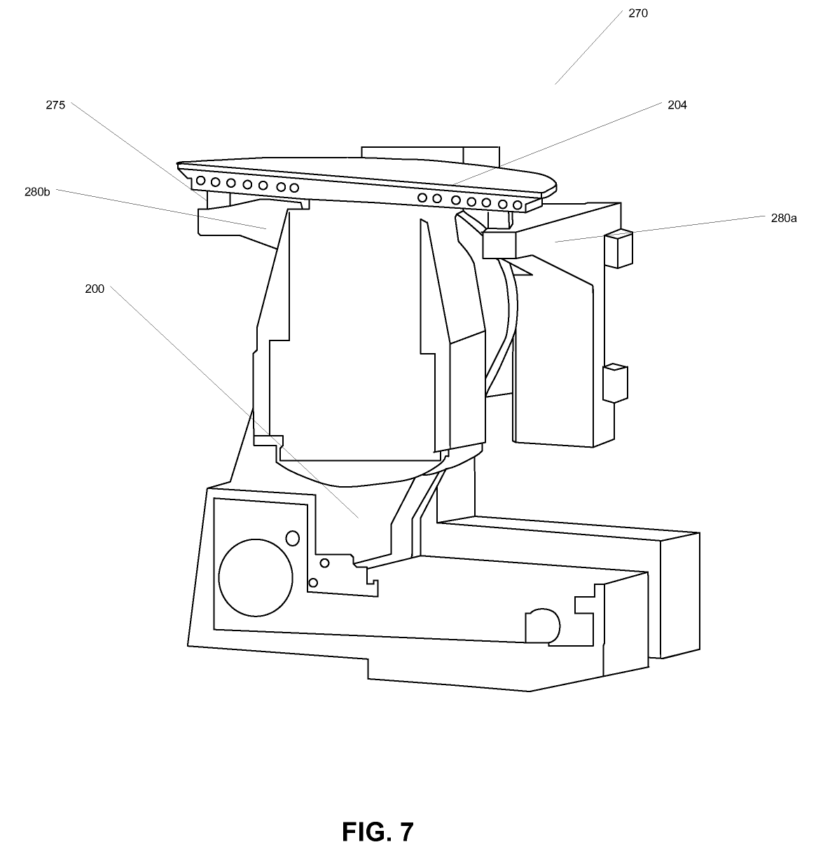

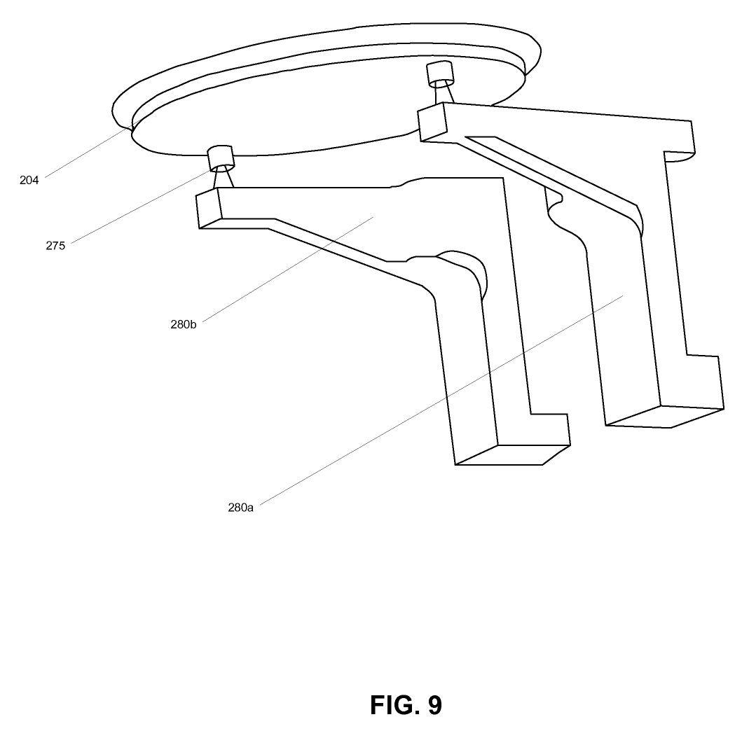

FIGS. 6-9 represent a second embodiment of the apparatus. In this embodiment, the conduit on the platen 204 is accessed via the bottom surface of the platen 204. As described above, a conduit is located within the platen 204. In this embodiment, the entrance and exit points on the platen 204 are located on its underside. As explained previously, the entrance and exit points on the platen 204 can be simply openings, or can include a connection mechanism such as a nozzle.

In one embodiment, the temperature regulating apparatus 270 is “U” shaped, where two protruding arms 280 form the legs of the “U”. The apparatus 270 and roplat 200 are moved toward one another, such that the roplat 200 enters into the open end of the “U” shape, and then the relative heights of the apparatus 270 and roplat 200 are aligned so as to bring the openings on the underside of the platen 204 in contact with the connection mechanism 275 on the upper side of the apparatus 270, as shown in FIG. 6. In some embodiments, an air bearing system is used to lower the platen onto the arms 280 of the apparatus. In certain embodiments, a motor within the roplat is used to lower the platen so that it contacts the arms 280. In other embodiments, the apparatus 220 includes means to raise the protruding arms 280 so as to contact the platen.

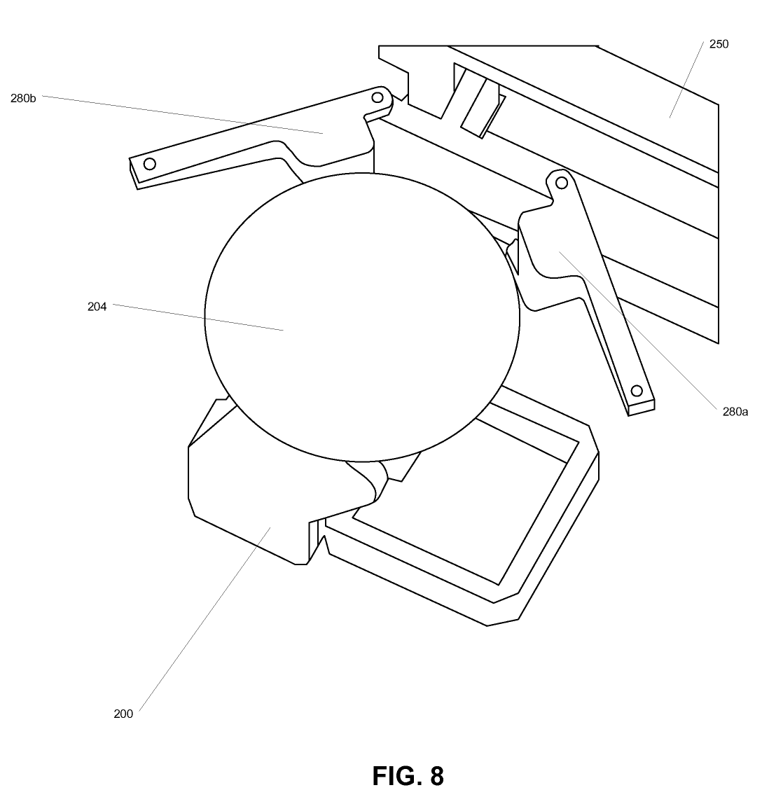

In a second embodiment, the protruding arms 280 of apparatus 270 are movable. The apparatus includes a motor capable of actuating the arms through a preferably rotary trajectory. One particular embodiment is shown in FIG. 8. In this Figure, two movable arms 280a, 280b are used, whereby one supplies fluid to the platen 204 and the other arm 280b provides the return path. The two arms 280 are rotated about one or more axes so as to move them into position below the platen 204, by virtue of a motor or other suitable mechanism (not shown). The movable arms 280 are then lifted to contact the platen 204, or alternatively, the platen 204 is lowered to meet the contacts 275 on the arms 280, as described above. Once connected, fluid can pass through the conduits as described above. To disengage, the platen and the arms are moved apart relative to one another. The arms are then rotated away from the platen, and therefore are not in the ion beam path.

Alternatively, a single arm 280, having two or more conduit termination ports 275 for attachment to the platen, can be used. This single arm can be stationary, or movable, as described above.

The temperature regulating apparatus, once connected, can be used in a number of ways. In one embodiment, this apparatus is the only mechanism used to regulate the temperature of the platen 204. In other words, the intermittent connections between the apparatus and the platen 204 are sufficient to regulate the platen temperature throughout all phases of the ion implant process. This is applicable in situations where the entire ion implant is performed at a constant temperature. In this situation, the platen is continuously regulated by a single fluid source fed to the platen through the apparatus. In another embodiment, the conduits in the apparatus are in communication with a plurality of fluid sources, such as extremely cold fluids (liquid nitrogen, etc), nitrogen, carbon dioxide or other fluids. In this embodiment, the apparatus selects the appropriate fluid source to pass through the conduit and into the platen to realize the desired temperature. Such a selection may be accomplished using control valves or any suitable mechanism. Alternatively, the apparatus may comprise a plurality of connection ports 245, each pair associated with a specific fluid path. In one words, one pair may be the supply and return for liquid nitrogen, while another pair may be the supply and return for water. The apparatus then aligns with the platen in one of a plurality of viable docking positions, depending on the selected fluid source. Such a configuration allows a plurality of different fluids to flow through the platen, and therefore a plurality of different operating temperatures can be achieved.

In another embodiment, the apparatus is only used in certain modes of operation. For example, the apparatus may only be used to deliver cryogenic fluids to the platen during cold ion implant. During other process steps, the temperature of the platen is regulated using conventional methods, such as water cooling.

Intermittent cooling of the platen using this apparatus is an effective technique to regulate the temperature of the platen. An existing aluminum platen has a thermal capacitance of about 3000 Joules/° C. A 1E15@20 kV, 15 mA implant is approximately 3000 J. Therefore, one such implant increases the temperature of the platen about 1° C. Cold implants can typically be performed at temperatures up to roughly −60° C. Therefore, if the apparatus was able to cool the platen to a temperature of about −100° C., up to 4 implant cycles could be performed before the platen would need to be cooled again. There are two types of cooling cycles that need to be performed. Initial cool down from room temperature (20° C.) to working temperature (−60° C.) is expected to take about 10 minutes. Recooling the platen between implants or sets of implants is much quickly, preferably on the order of seconds. This insures acceptable throughput.

What is claimed is:

1. A mechanism for regulating the temperature of a workpiece, comprising:
a. A platen upon which said workpiece is positioned, having a conduit therein, where said conduit terminates on each end at a port;
b. An apparatus, comprising a plurality of connectors adapted to contact said ports of said platen, wherein said connectors provide a supply and return path for fluid to pass through said conduit; and
c. means to move said apparatus and said platen toward one another such that said ports in said platen and said connections ports form a fluid-tight seal.

2. The mechanism of claim 1, wherein said ports are located on the side of said platen.

3. The mechanism of claim 2, wherein said apparatus comprises said means to move toward said platen.

4. The mechanism of claim 1, wherein said ports are located on the underside of said platen.

5. The mechanism of claim 4, wherein said apparatus comprises a protruding arm, having a plurality of connectors on its top surface.

6. The mechanism of claim 4, wherein said apparatus comprises a plurality of protruding arms, each having a connector on their respective top surfaces.

7. The mechanism of claim 4, wherein said arm is stationary.

8. The mechanism of claim 6, wherein said apparatus comprises said means to rotate said arms toward said platen so that said ports and said connectors align.

9. The mechanism of claim 1, wherein said apparatus comprises valves to enable and disable the flow fluid through said conduit.

10. The mechanism of claim 1, wherein said fluid is selected from the group consisting of nitrogen, liquid nitrogen, carbon dioxide, helium and Fluorinert.

11. A method of regulating the temperature of a workpiece, comprising:
a. Providing a platen upon which said workpiece is positioned, having a conduit therein, where said conduit terminates on each end at a port; and an apparatus, comprising a plurality of connectors adapted to contact said ports of said platen, wherein said connectors provide a supply and return path for fluid to pass through said conduit;
b. Moving said platen and said apparatus toward one another so that said ports and said connectors engage, forming a fluid-tight seal; and
c. Passing a fluid through said conduit.

12. The method of claim 11, wherein said fluid is selected from the group consisting of nitrogen, liquid nitrogen, carbon dioxide, helium and Fluorinert.

13. The method of claim 11, wherein said ports are located on the side of said platen and said moving step comprises moving said platen toward said apparatus.

14. The method of claim 11, wherein said ports are located on the side of said platen and said moving step comprises moving said apparatus toward said platen.

15. The method of claim 11, wherein said ports are located on the underside of said platen.

16. The method of claim 15, wherein said apparatus comprises a protruding arm having a plurality of connectors on its top surface.

17. The method of claim 15, wherein said apparatus comprises a plurality of protruding arms each having a connector on its top surface.

18. The method of claim 17, wherein said moving step comprises rotating said arms toward the underside of said platen.
